(19) United States
(12) Patent Application Publication
(10) Pub. No.: US 2024/0339502 A1
(43) Pub. Date: Oct. 10, 2024

(54) SILICON CARBIDE SEMICONDUCTOR DEVICE AND METHOD FOR MANUFACTURING THE SAME

(71) Applicant: FUJI ELECTRIC CO., LTD., Kawasaki-shi (JP)

(72) Inventor: Tomohiro MORIYA, Matsumoto-city (JP)

(73) Assignee: FUJI ELECTRIC CO., LTD., Kawasaki-shi (JP)

(21) Appl. No.: 18/587,335

(22) Filed: Feb. 26, 2024

(30) Foreign Application Priority Data
Apr. 5, 2023 (JP) 2023-061385

(51) Int. Cl. H01L 29/16; H01L 29/06; H01L 29/66

(52) U.S. Cl. CPC H01L 29/1608; H01L 29/0638; H01L 29/66068

(57) ABSTRACT

Provided is a SiC semiconductor device that enables ohmic contact between the main region and the main electrode and can suppress large surface irregularities in other regions. The SiC semiconductor device includes, an active part and a voltage withstanding structure part and includes a drift layer formed of SiC; a base region formed of SiC and provided on the top face side of the drift layer in the active part; main regions 6a, 6b formed of Sic, provided on the top face side of the base region, and containing a 3C structure in at least the top face portion thereof; a channel stopper region 6c formed of SiC with a 4H structure and provided on the top face side of the drift layer in the voltage withstanding structure part; an insulated gate electrode structure; and an inorganic insulating film 10 provided on the top face of the channel stopper region.

### CROSS-REFERENCE TO RELATED APPLICATION

This application claims benefit of priority under 35 USC 119 based on Japanese Patent Application No. 2023-061385 filed on Apr. 5, 2023, the entire contents of which are incorporated by reference herein.

### BACKGROUND OF THE INVENTION

### 1. Field of the Invention

The present disclosure relates to a Sic semiconductor device including silicon carbide (SiC) and a method for manufacturing the device.

### 2. Description of the Related Art

JP 2009-49198 A discloses a semiconductor device that is manufactured by implanting phosphorus ions into a substrate of hexagonal single crystal silicon carbide to form an amorphous layer, recrystallizing the amorphous layer by heat treatment into cubic single crystals of n type silicon carbide, and depositing nickel on the top surface of the n type silicon carbide to form an electrode.

WO 2017/042963 A1 discloses a semiconductor device that has, in an n⁻ type epitaxial growth layer formed on a first main surface of an n⁺ type SiC substrate formed of 4H-SiC, an n⁺ type source region and has an n⁺ type 3C-SiC region and a p⁺ type potential fixing region that are formed in the n⁺ type source region. In the semiconductor device, a barrier metal film is formed in contact with the n⁺ type 3C-SiC region and the p⁺ type potential fixing region, and a source wiring electrode is formed on the barrier metal film.

In a SiC semiconductor device, a source region (main region) formed of 3C-SiC has been studied for ohmic contact with a source electrode (main electrode).

Meanwhile, 3C-SiC has more crystal defects than 4H-SiC and may give larger surface irregularities. On a surface with larger irregularities, for example, an insulating film formed thereon may have poor adhesiveness.

### SUMMARY OF INVENTION

Under such circumstances, the present disclosure is intended to provide a SiC semiconductor device that enables ohmic contact between the main region and the main electrode and can suppress large surface irregularities in other regions and a method for manufacturing the device.

An aspect of the disclosure is a SiC semiconductor device including, in plan view, an active part and a voltage withstanding structure part surrounding the periphery of the active part. The SiC semiconductor device includes a first conductivity type drift layer formed of silicon carbide and provided over the active part and the voltage withstanding structure part; a second conductivity type base region formed of silicon carbide and provided on the top face side of the drift layer in the active part; a first conductivity type main region formed of silicon carbide, provided on the top face side of the base region, and containing a 3C structure in at least the top face portion thereof; a channel stopper region formed of silicon carbide with a 4H structure and provided on the top face side of the drift layer in the voltage withstanding structure part and along the outer periphery of the voltage withstanding structure part in plan view; an insulated gate electrode structure provided in contact with the main region and the base region; and an inorganic insulating film provided on the top face of the channel stopper region.

Another aspect of the disclosure is a method for manufacturing a silicon carbide semiconductor device having, in plan view, an active part and a voltage withstanding structure part surrounding the periphery of the active part. The method for manufacturing a SiC semiconductor device includes providing a first conductivity type drift layer formed of silicon carbide over the active part and the voltage withstanding structure part; forming a second conductivity type base region formed of silicon carbide on the top face side of the drift layer in the active part; subjecting the top face side of the base region to ion implantation to form a first conductivity type main region formed of silicon carbide and containing a 3C structure in at least the top face portion thereof; subjecting the top face side of the drift layer in the voltage withstanding structure part to ion implantation to form a channel stopper region formed of silicon carbide with a 4H structure along the outer periphery of the voltage withstanding structure part in plan view; forming an insulated gate electrode structure in contact with the main region and the base region; and providing an inorganic insulating film on the top face of the channel stopper region.

### BRIEF DESCRIPTION OF DRAWINGS

FIG. 1 is a plan view schematically illustrating an example of a SiC semiconductor device pertaining to a first embodiment;

FIG. 2 is a longitudinal sectional view illustrating a cross-sectional structure taken along line A-A in FIG. 1;

FIG. 3 is a schematic sectional view illustrating an example method for manufacturing a SiC semiconductor device pertaining to the first embodiment;

FIG. 4 is a schematic sectional view illustrating an example method for manufacturing a SiC semiconductor device pertaining to the first embodiment, following FIG. 3;

FIG. 5 is a schematic sectional view illustrating an example method for manufacturing a SiC semiconductor device pertaining to the first embodiment, following FIG. 4;

FIG. 6 is a schematic sectional view illustrating an example method for manufacturing a SiC semiconductor device pertaining to the first embodiment, following FIG. 5;

FIG. 7 is a schematic sectional view illustrating an example method for manufacturing a SiC semiconductor device pertaining to the first embodiment, following FIG. 6;

FIG. 8 is a schematic sectional view illustrating an example method for manufacturing a SiC semiconductor device pertaining to the first embodiment, following FIG. 7;

FIG. 9 is a schematic sectional view illustrating an example method for manufacturing a SiC semiconductor device pertaining to the first embodiment, following FIG. 8;

FIG. 10 is a schematic sectional view illustrating an example method for manufacturing a SiC semiconductor device pertaining to the first embodiment, following FIG. 9;

FIG. 11 is a schematic sectional view illustrating an example method for manufacturing a SiC semiconductor device pertaining to the first embodiment, following FIG. 10;

FIG. 12 is a schematic sectional view illustrating an example method for manufacturing a SiC semiconductor device pertaining to a second embodiment; and

FIG. 13 is a schematic sectional view illustrating an example method for manufacturing a SiC semiconductor device pertaining to the second embodiment.

### DETAILED DESCRIPTION

First and second embodiments of the present disclosure will now be described with reference to drawings. In the description of drawings, identical or similar components are indicated by an identical or similar sign and are not described. However, the drawings are schematic, and the relationship between thickness and plan dimension, the ratio of thicknesses of layers, or the like may differ from the actual ones. The dimensional relationships or ratios may differ between drawings. The first and second embodiments described below are merely illustrative examples of devices or methods for embodying the technical ideas of the present disclosure, and the technical ideas of the disclosure do not specify the materials, shapes, structures, arrangements, or the like of components as follows.

In the present description, the source region of a metal-oxide semiconductor field-effect transistor (MOSFET) is “one main region (first main region)” selectable as the emitter region of an insulated gate bipolar transistor (IGBT). In a thyristor such as a MOS-controlled static induction thyristor (SI thyristor), “one main region” is selectable as the cathode region. The drain region of a MOSFET is “the other main region (second main region)” of a semiconductor device that is selectable as the collector region in an IGBT and is selectable as the anode region in a thyristor. In the present description, a region simply called a “main region” means a first main region or a second main region reasonable on the basis of the general knowledge of a person skilled in the art. An insulated gate electrode structure may be of the trench gate type or of the planar gate type.

In the following description, the definitions of directions such as up and down directions are merely for convenience of explanation and do not limit the technical ideas of the disclosure. For example, when an object is rotated by 90° and observed, the up and down directions are converted to left and right directions, and when an object is rotated by 180° and observed, the up and down directions are inverted, needless to say. A “top face” may also be read as a “front face”, and the “bottom face” may also be read as a “back face”.

In the following description, a case in which a first conductivity type is an n type and a second conductivity type is a p type will be described as an example. However, the relationship of the conductivity types may be inverted to set the first conductivity type to the p type and the second conductivity type to the n type. A semiconductor region denoted by n or p with + or − means that such a semiconductor region has a higher or lower impurity concentration than a semiconductor region denoted by n or p without + or −. It should be noted that a semiconductor region denoted by n and a semiconductor region denoted by the same n may not have exactly the same impurity concentration.

SiC crystals have polymorphism, and the main polymorphisms are cubic 3C and hexagonal 4H and 6H. It has been reported that at room temperature, 3C-SiC has a bandgap of 2.23 eV, 4H-SiC has a bandgap of 3.26 eV, and 6H-SiC has a bandgap of 3.02 eV. In the following description, a case in which 4H-SiC and 3C-SiC are mainly used will be illustrated.

### First Embodiment

### <Structure of SiC Semiconductor Device>

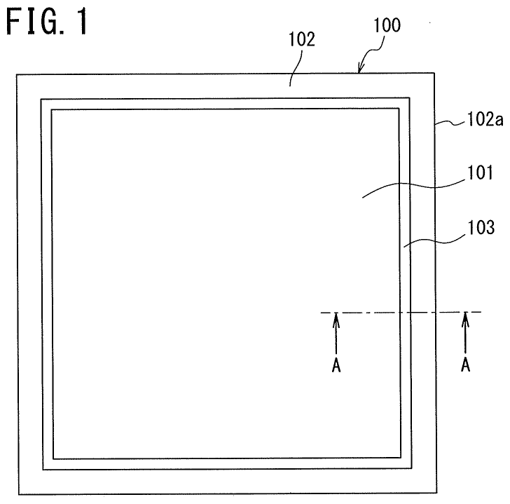

A SiC (silicon carbide) semiconductor device (semiconductor chip) 100 pertaining to a first embodiment includes, as illustrated in FIG. 1, an active part 101, for example, having a rectangular planar shape and a voltage withstanding structure part 102 surrounding the periphery of the active part 101, in plan view. The SiC semiconductor device 100 also includes, between the active part 101 and the voltage withstanding structure part 102, a region 103 surrounding the active part 101, in plan view.

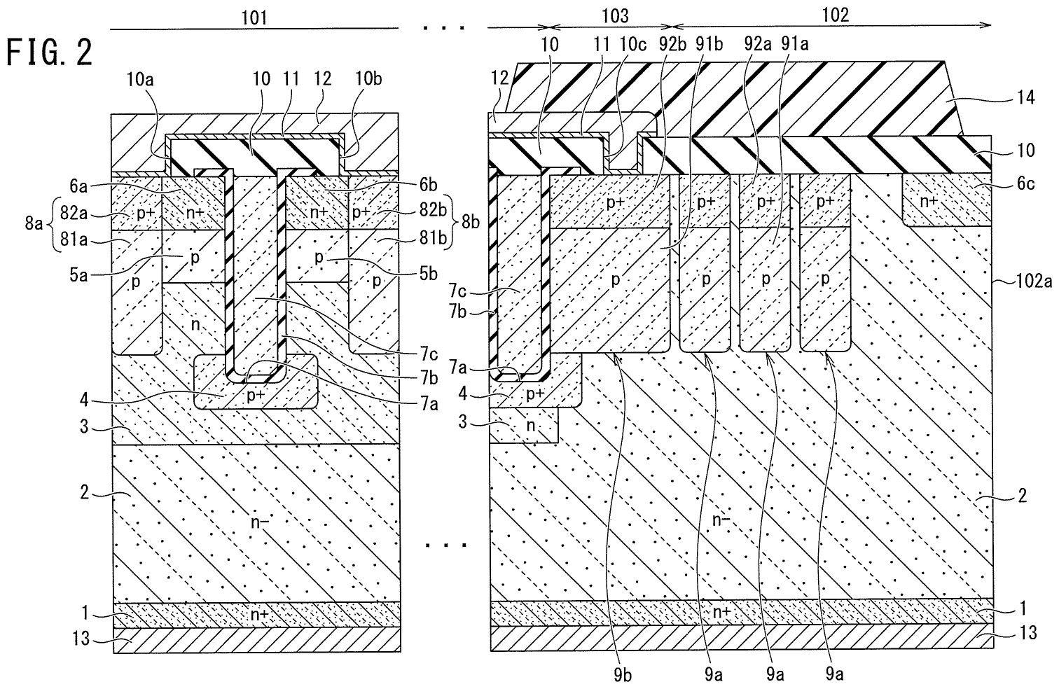

FIG. 2 is a sectional view taken along line A-A in FIG. 1. In FIG. 2, a part of the active part 101 is not illustrated. As illustrated in FIG. 2, the active part 101 includes an active element, and the region 103 includes a ring region 9b, as an example. The voltage withstanding structure part 102 includes, as the termination structure, a plurality of field relaxation regions 9a and a channel stopper region 6c described later, as an example.

As illustrated in FIG. 2, the SiC semiconductor device 100 includes a trench-gate type MOSFET as the active element, as an example. FIG. 2 illustrates a unit cell including an insulated gate electrode structure (7b, 7c) embedded in one trench 7a, but in an actual device, a large number of these unit cells are arranged periodically.

The SiC semiconductor device 100 includes a first conductivity type (n-type) drift layer 2 provided over the active part 101, the voltage withstanding structure part 102, and the region 103. The drift layer 2 includes, for example, an epitaxial growth layer formed of SiC such as 4H-SiC. The drift layer 2 has an impurity concentration of, for example, about 1×10¹⁵ cm⁻³ or more and 5×10¹⁶ cm⁻³ or less. The drift layer 2 has a thickness of, for example, about 1 μm or more and 100 μm or less. The impurity concentration and the thickness of the drift layer 2 may be appropriately adjusted according to withstand voltage specifications or the like.

In the active part 101, a first conductivity type (n type) current spreading layer (CSL) 3 having a higher impurity concentration than the drift layer 2 is selectively provided on the top face side of the drift layer 2. The bottom face of the current spreading layer 3 is in contact with the top face of the drift layer 2. The current spreading layer 3 is, for example, a region formed of SiC such as 4H-SiC and formed by subjecting the drift layer 2 to ion implantation of n type impurities. The current spreading layer 3 has an impurity concentration of, for example, about 5×10¹⁶ cm⁻³ or more and 5×10¹⁷ cm⁻³ or less. The current spreading layer 3 is not necessarily provided. When no current spreading layer 3 is provided, the drift layer 2 may extend to the region of the current spreading layer 3. The current spreading layer 3 may be provided over the voltage withstanding structure part 102 and the region 103.

In the active part 101, second conductivity type (p type) base regions 5a, 5b are selectively provided on the top face side of the current spreading layer 3. The bottom faces of the base regions 5a, 5b are in contact with the top face of the current spreading layer 3. When no current spreading layer 3 is provided, the bottom faces of the base regions 5a, 5b are in contact with the top face of the drift layer 2. The base regions 5a, 5b are, for example, regions of a SiC formed by subjecting the drift layer 2 to ion implantation of p type impurities. The base regions 5a, 5b may include an epitaxial growth layer formed of SiC such as 4H-SiC. The base regions 5a, 5b have an impurity concentration of, for example, about 1×10¹⁶ cm⁻³ or more and 1×10¹⁸ cm⁻³ or less.

On the top face sides of the base regions 5a, 5b, first conductivity type (n⁺ type) first main regions (source regions) 6a, 6b having a higher impurity concentration than the drift layer 2 are selectively provided. The bottom face of the source region 6a is in contact with the top face of the base region 5a, and the bottom face of the source region 6b is in contact with the top face of the base region 5b. The source regions 6a, 6b are, for example, regions of a SiC formed by subjecting the drift layer 2 to ion implantation of n type impurities. The source regions 6a, 6b have an impurity concentration of, for example, about 1×10²⁰ cm⁻³ or more and 1×10²¹ cm⁻³ or less. The source regions 6a, 6b contain 3C-SiC and 4H-SiC. More specifically, at least each top face portion of the source regions 6a, 6b contains a 3C structure. Each top face portion of the source regions 6a, 6b contains 3C-SiC at 10% or more. Hereinafter, 3C-SiC may also called a 3C structure, and 4H-SiC may also called a 4H structure.

From the top faces of the source regions 6a, 6b in the normal direction of the top faces of the source regions 6a, 6b (in the depth direction), a trench 7a penetrating the source regions 6a, 6b and the base regions 5a, 5b is provided. The bottom face of the trench 7a reaches the current spreading layer 3. The trench 7a has a width of, for example, about 1 μm or less. The left face of the trench 7a is in contact with the source region 6a and the base region 5a. The right face of the trench 7a is in contact with the source region 6b and the base region 5b. The trench 7a may have a plane pattern of a stripe extending in the back direction and the front direction of the plane of FIG. 2 or may have a plane pattern of dots.

On the bottom face and both side faces of the trench 7a, a gate insulating film 7b is provided. In the trench 7a, a gate electrode 7c is embedded on the gate insulating film 7b. The gate insulating film 7b and the gate electrode 7c constitute a trench-gate type insulated gate electrode structure (7b, 7c).

As the gate insulating film 7b, a single layer film of one of a silicone oxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (Zro₂) film, a tantalum oxide (Ta₂O₅) film, and a bismuth oxide (Bi₂O₃) film, a composite film prepared by stacking a plurality of such films, or the like is usable. As the material of the gate electrode 7c, for example, a polysilicon layer containing p type impurities or n type impurities at a high impurity concentration (doped polysilicon layer) or a high-melting point metal such as titanium (Ti), tungsten (W), or nickel (Ni) is usable.

In the current spreading layer 3 and on the bottom part of the trench 7a, a second conductivity type (p⁺ type) gate bottom protection region 4 is provided. The top face of the gate bottom protection region 4 is in contact with the bottom face of the trench 7a. The top face of the gate bottom protection region 4 may not be in contact with the bottom face of the trench 7a. The gate bottom protection region 4 has an impurity concentration of, for example, about 1×10¹⁷ cm⁻³ or more and 1×10¹⁹ cm⁻³ or less. The gate bottom protection region 4 is, for example, a region of a SiC formed by subjecting the current spreading layer 3 to ion implantation of p type impurities. The bottom face of the gate bottom protection region 4 may be deeper or shallower than the bottom face of the current spreading layer 3.

On the top face side of the current spreading layer 3, second conductivity type (p type) buried regions 81a, 81b are selectively provided to be in contact with the base regions 5a, 5b. The bottom faces of the buried regions 81a, 81b are in contact with the current spreading layer 3. The side face of the buried region 81a is in contact with the current spreading layer 3 and the base region 5a, and the side face of the buried region 81b is in contact with the current spreading layer 3 and the base region 5b. The buried regions 81a, 81b are, for example, regions of a SiC formed by subjecting the current spreading layer 3 to ion implantation of p type impurities. The buried regions 81a, 81b have an impurity concentration of, for example, about not less than 1×10¹⁷ cm⁻³ and less than 1×10¹⁹ cm⁻³. The buried regions 81a, 81b includes 4H-SiC.

On the top face sides of the buried regions 81a, 81b, p⁺ type base contact regions 82a, 82b having a higher impurity concentration than the buried region 81a are selectively provided. The bottom face of the base contact region 82a is in contact with the top face of the buried region 81a, and the side face of the base contact region 82a is in contact with the source region 6a. The bottom face of the base contact region 82b is in contact with the top face of the buried region 81b, and the side face of the base contact region 82b is in contact with the source region 6b. The base contact regions 82a, 82b are, for example, regions of a SiC formed by subjecting the drift layer 2 to ion implantation of p type impurities. The base contact regions 82a, 82b have a higher impurity concentration than the buried regions 81a, 81b and have an impurity concentration of, for example, about 1×10¹⁹ cm⁻³ or more and 1×10²¹ cm⁻³ or less. The base contact regions 82a, 82b include 4H-SiC.

In the voltage withstanding structure part 102, a plurality of second conductivity type (p type) field relaxation regions 9a are selectively provided on the top face side of the drift layer 2. In an example illustrated in FIG. 2, three field relaxation regions 9a are provided on the top face side of the drift layer 2. The field relaxation regions 9a are concentric guard rings (field limiting rings) in plan view, not illustrated in the drawings. The field relaxation regions 9a are separated from each other by the drift layer 2. The bottom faces of the field relaxation regions 9a are in contact with the top face of the drift layer 2. When a current spreading layer 3 is provided, the bottom faces of the field relaxation regions 9a are in contact with the top face of the current spreading layer 3. Each field relaxation region 9a is, for example, a region of a SiC formed by subjecting the drift layer 2 to ion implantation of p type impurities. More specifically, the field relaxation region 9a is a region formed of 4H-SiC.

The field relaxation region 9a has a p type first portion 91a and a p⁺ type second portion 92a. The second portion 92a is located shallower in the depth direction than the first portion 91a, and the bottom face of the second portion 92a is in contact with the top face of the first portion 91a. The first portion 91a has an impurity concentration of, for example, about not less than 1×10¹⁷ cm⁻³ and less than 1×10¹⁹ cm⁻³. The second portion 92a has an impurity concentration of, for example, about 1×10¹⁹ cm⁻³ or more and 1×10²¹ cm⁻³ or less, which is higher than the impurity concentration of the first portion 91a. The first portion 91a located deeper than the second portion 92a is set to have a lower impurity concentration than that of the second portion 92a, and accordingly the field relaxation region 9a has higher withstand voltage characteristics against electric fields.

In the voltage withstanding structure part 102, a first conductivity type (n⁺ type) channel stopper region 6c is provided on the top face side of the drift layer 2. The bottom face of the channel stopper region 6c is in contact with the top face of the drift layer 2. When a current spreading layer 3 is provided, the bottom face of the channel stopper region 6c is in contact with the top face of the current spreading layer 3. The channel stopper region 6c is provided along the outer periphery 102a of the SiC semiconductor device (semiconductor chip) 100 illustrated in FIG. 1 in plan view and more specifically provided along the outer periphery 102a of the voltage withstanding structure part 102. The channel stopper region 6c is so provided as to run along the outer periphery 102a in plan view to surround the voltage withstanding structure part 102.

The channel stopper region 6c suppresses deterioration of the withstand voltage characteristics of the voltage withstanding structure part 102. More specifically, the channel stopper region 6c prevents a depletion layer formed in the voltage withstanding structure part 102 from reaching the outer periphery 102a of the SiC semiconductor device (semiconductor chip) 100. The face on the outer periphery 102a of the SiC semiconductor device (semiconductor chip) 100 is a dicing face with a rough surface formed in a process of making the SiC semiconductor device 100 into individual pieces. If a depletion layer reaches such a face, leak current may be generated, and the withstand voltage characteristics may deteriorate. To address this concern, a channel stopper region 6c having the same electric potential as a drain electrode described later is provided, and thus a depletion layer is difficult to reach the face on the outer periphery 102a.

The channel stopper region 6c is, for example, a region of a 4H-SiC formed by subjecting the drift layer 2 to ion implantation of n type impurities. The channel stopper region 6c has an impurity concentration of, for example, about 1×10¹⁹ cm⁻³ or more and 3×10²⁰ cm⁻³ or less. 4H-SiC has fewer crystal defects than 3C-SiC. Hence, the exposed face of a semiconductor region formed of 4H-SiC has fewer irregularities than the exposed face of a semiconductor region formed of 3C-SiC. When the channel stopper region 6c is formed of 4H-SiC, the top face of the channel stopper region 6c (see FIG. 2) is prevented to have large irregularities or a large surface roughness. This suppresses deterioration of the adhesion to an insulating film 10 described later and formed on the top face of the channel stopper region 6c. The dimension in the depth direction of the channel stopper region 6c is, for example, about 0.2 μm or more and 0.5 μm or less, and the dimension in the width direction is, for example, about 10 μm or more and 70 μm or less.

In the region 103, a second conductivity type (p type) ring region 9b is selectively provided on the top face side of the drift layer 2. The bottom face of the ring region 9b is in contact with the top face of the drift layer 2. When a current spreading layer 3 is provided, the bottom face of the ring region 9b is in contact with the top face of the current spreading layer 3. The ring region 9b is, for example, a region of a SiC formed by subjecting the drift layer 2 to ion implantation of p type impurities. More specifically, the ring region 9b is a region formed of 4H-SiC. The ring region 9b is a ring-shaped portion surrounding the edge of the active part 101 in plan view, not illustrated in the drawings.

The ring region 9b has a p type first portion 91b and a p⁺ type second portion 92b. The second portion 92b is located shallower in the depth direction than the first portion 91b, and the bottom face of the second portion 92b is in contact with the top face of the first portion 91b. The first portion 91b has an impurity concentration of, for example, about not less than 1×10¹⁷ cm⁻³ and less than 1×10¹⁹ cm⁻³. The second portion 92b has an impurity concentration of, for example, about 1×10¹⁹ cm⁻³ or more and 1×10²¹ cm⁻³ or less, which is higher than the impurity concentration of the first portion 91b.

On the top face side of the gate electrode 7c, the top face side of the region 103, and the top face side of the voltage withstanding structure part 102, an insulating film 10 is selectively provided. In the voltage withstanding structure part 102, the insulating film 10 is provided on the top faces of the field relaxation regions 9a and the channel stopper region 6c. More specifically, the insulating film 10 is provided in a position to cover the second portions 92a of the field relaxation regions 9a and the channel stopper region 6c. The insulating film 10 is an inorganic insulating film. The insulating film 10 is constituted of a single layer film such as a silicone oxide film containing boron (B) and phosphorus (P) (BPSG film), a silicone oxide film containing phosphorus (P) (PSG film), a non-doped silicone oxide film called “NSG” and containing neither phosphorus (P) nor boron (B), a silicone oxide film containing boron (B) (BSG film), and a silicon nitride film (Si₃N₄ film), or a stacked-layer film thereof, for example. The insulating film 10 has contact holes 10a, 10b through which the top faces of the source regions 6a, 6b and the base contact regions 82a, 82b are exposed. The insulating film 10 also has a contact hole 10c through which the top face of the ring region 9b, more specifically the top face of the second portion 92b, is exposed.

A first main electrode (source electrode) (11, 12) is provided so as to cover the insulating film 10, the top faces of the source regions 6a, 6b and the top faces of the base contact regions 82a, 82b exposed through the contact holes 10a, 10b, and the top face of the ring region 9b exposed through the contact hole 10c. The source electrode (11, 12) includes a lower barrier metal layer 11 and an upper source wiring electrode 12. For example, the barrier metal layer 11 includes a metal such as titanium nitride (TiN), titanium (Ti), or a TiN/Ti multilayer structure in which Ti is the lower layer. The barrier metal layer 11 is in direct contact with the source regions 6a, 6b, the base contact regions 82a, 82b, and the second portion 92b of the ring region 9b. The barrier metal layer 11 is in ohmic contact with the source regions 6a, 6b containing 3C-SiC at a low resistance.

The source wiring electrode 12 is electrically connected through the barrier metal layer 11 to the source regions 6a, 6b, the base contact regions 82a, 82b, and the ring region 9b. The source wiring electrode 12 is provided separately from a gate wiring electrode (not illustrated) that is electrically connected to the gate electrode 7c. The source wiring electrode 12, for example, includes a metal such as aluminum (Al), aluminum-silicon (Al—Si), aluminum-copper (Al—Cu), and copper (Cu).

On the top face of the insulating film 10, an insulating film 14 is provided. The outer peripheral edge portion of the insulating film 14 close to the outer periphery 102a is located to overlap with the channel stopper region 6c in plan view. In the voltage withstanding structure part 102 and the region 103, the insulating film 14 is provided in a position to cover the boundary between the source wiring electrode 12 and the insulating film 10. The insulating film 14 functions as a protective film to protect the SiC semiconductor device 100 against moisture or the like. In particular, the insulating film 14 prevents moisture from entering at the boundary between the source wiring electrode 12 and the insulating film 10. The insulating film 14 is an organic insulating film. The insulating film 14 is, for example, a resin material such as polyimide.

On the bottom face side of the drift layer 2, a first conductivity type (n⁺ type) second main region (drain region) 1 having a higher impurity concentration than the drift layer 2 is provided. The drain region 1, for example, includes a semiconductor substrate (SiC substrate) formed of 4H-SiC. The drain region 1 has an impurity concentration of, for example, about 1×10¹⁹ cm-3 or more and 3×10²⁰ cm⁻³ or less. The drain region 1 has a thickness of, for example, about 30 μm or more and 500 μm or less. Between the drift layer 2 and the drain region 1, a dislocation conversion layer or a recombination enhancement layer that is an n type buffer layer having a higher impurity concentration than the drift layer 2 and having a lower impurity concentration than the drain region 1 may be provided.

On the bottom face side of the drain region 1, a second main electrode (drain electrode) 13 is provided. As the drain electrode 13, for example, a single layer film of gold (Au) or a metal film in which titanium (Ti), nickel (Ni), and Au are stacked in this order from the drain region 1 is usable, and a metal film such as a molybdenum (Mo) film and a tungsten (W) film may be further stacked as the lowermost layer. Between the drain region 1 and the drain electrode 13, a drain contact layer such as a nickel silicide (NiSiₓ) film may be provided for ohmic contact.

The SiC semiconductor device according to the first embodiment during the operation applies a positive voltage to the drain electrode 13 while using the source electrode (11, 12) as a ground potential, and causes an inversion layer (a channel) to be formed in the respective base regions 5a and 5b toward the side surfaces of the trench 7a so as to be in the ON-state when a positive voltage of a threshold or greater is applied to the gate electrode 7c. In the ON-state, a current flows from the drain electrode 13 toward the source electrode (11, 12) through the drain region 1, the drift layer 2, the current spreading layer 3, the inversion layers of the base regions 5a and 5b, and the source regions 6a and 6b. When the voltage applied to the gate electrode 7c is smaller than the threshold, the SiC semiconductor device is led to be the OFF-state since no inversion channel is formed in the base region 5a, 5b, and no current flows from the drain electrode 13 toward the source electrode (11, 12).

In the SiC semiconductor device pertaining to the first embodiment, at least a portion of the source regions 6a, 6b in contact with the source electrode (11, 12) includes 3C-SiC, whereas the channel stopper region 6c is formed of 4H-SiC, which has fewer crystal defects than 3C-SiC. The channel stopper region 6c is formed of 4H-SiC having fewer crystal defects than 3C-SiC, and thus the top face of the channel stopper region 6c is prevented to have large irregularities. This can suppress deterioration of the adhesion between the top face of the channel stopper region 6c and the insulating film 10. Accordingly, the reliability of the voltage withstanding structure part 102 can be prevented from deteriorating. At least a portion of the source regions 6a, 6b in contact with the source electrode (11, 12) contains 3C-SiC, and thus the source regions 6a, 6b can be in ohmic contact with the source electrode (11, 12) at a low resistance without forming a silicide layer such as a nickel (Ni) silicide layer. Accordingly, disadvantages such as silicide layer release can be suppressed as compared with when a silicide layer is formed.

### <Method for Manufacturing SiC Semiconductor Device>

An example method for manufacturing the SiC semiconductor device pertaining to the first embodiment will next be described. The method for manufacturing a SiC semiconductor device described below is an example, and the manufacturing can be achieved by various other manufacturing methods including the alternative embodiment, within the scope described in claims, needless to say.

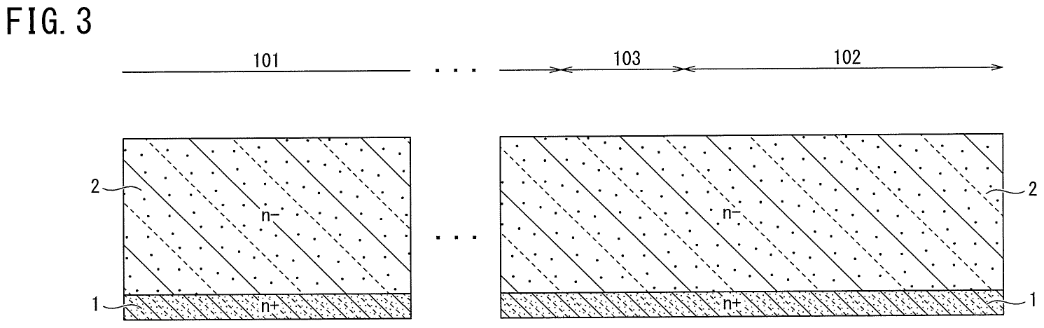

First, as illustrated in FIG. 3, a semiconductor substrate (SiC substrate) 1 formed of an n⁺ type 4H-SiC containing n type impurities such as nitrogen (N) is prepared. The top face of the SiC substrate 1, for example, has an off angle of 3 degrees to 8 degrees from {0001} plane. On the top face of the SiC substrate 1, a drift layer 2 of an n-type 4H-SiC containing n type impurities such as nitrogen (N) and having a lower impurity concentration than the SiC substrate 1 is epitaxially grown. More specifically, over the active part 101, the voltage withstanding structure part 102, and the region 103, a first conductivity type drift layer 2 of silicon carbide is formed.

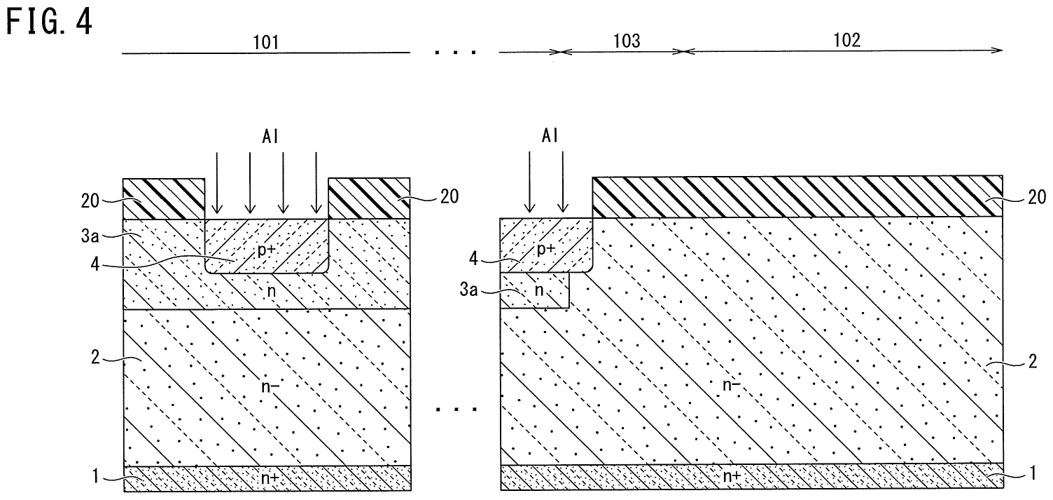

Next, as illustrated in FIG. 4, the top face of the drift layer 2 in the active part 101 is subjected to ion implantation of n type impurities such as N to form an n type layer 3a of an n type 4H-SiC having a higher impurity concentration than that of the drift layer 2. The n type layer 3a may be formed in the upper part of the drift layer 2 by epitaxial growth. A mask pattern 20 of a photoresist film is formed on the top face of the n type layer 3a by a photolithographic technology. The mask pattern 20 is used as an ion implantation mask, and p type impurities such as aluminum (Al) are selectively ion implanted. As a result, in the upper part of the n type layer 3a, a p⁺ type gate bottom protection region 4 is selectively formed. The mask pattern 20 is then removed. The mask pattern 20 may be, for example, a hard mask pattern formed of an oxide film.

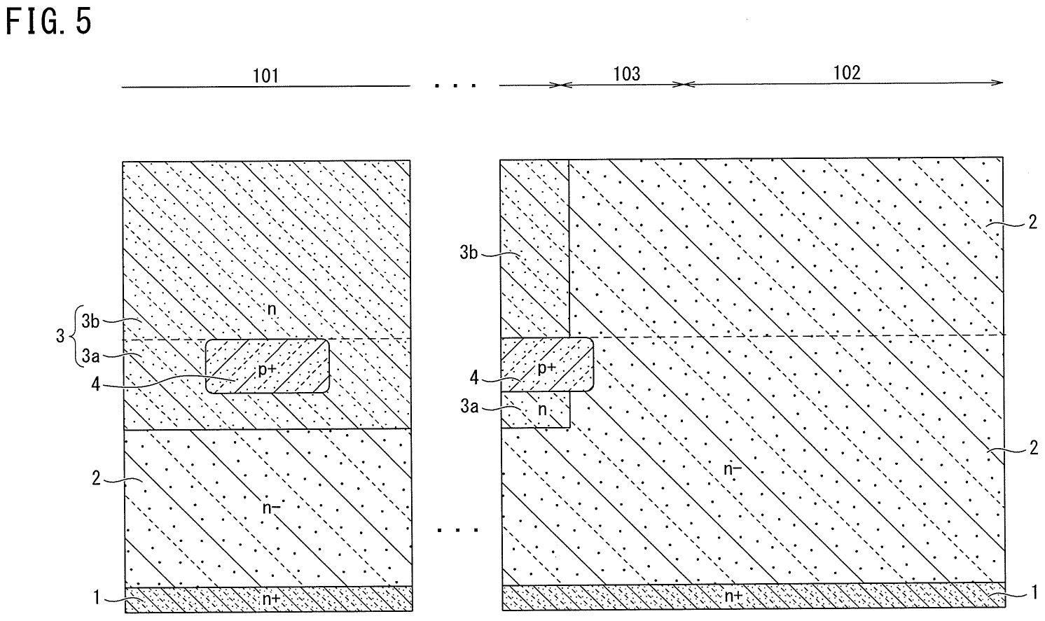

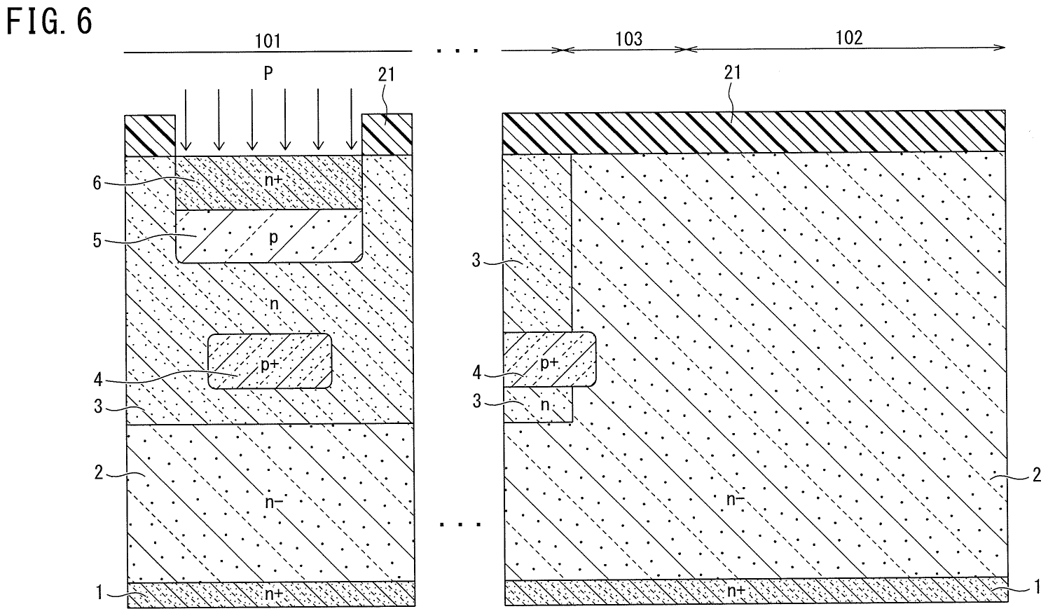

Next, as illustrated in FIG. 5, on the top faces of the drift layer 2, the n type layer 3a, and the gate bottom protection region 4, an n type 4H-SiC is epitaxially grown to increase the thickness of the drift layer 2. The top face of the n type layer 3a is subjected to ion implantation of n type impurities such as N to form an n type layer 3b of an n type 4H-SiC having a higher impurity concentration than that of the drift layer 2. As a result, in the active part 101, a current spreading layer 3 including the n type layer 3a and the n type layer 3b is formed. Not illustrated in drawings, the current spreading layer 3, for example, with a photoresist film as the mask pattern is subjected to selective ion implantation of p type impurities such as aluminum (Al). As a result, as illustrated in FIG. 6, a base region 5 is selectively formed on the top face side of the current spreading layer 3 in the active part 101. The mask pattern is then removed. The mask pattern may be, for example, a hard mask pattern formed of an oxide film.

Next, as illustrated in FIG. 6, a mask pattern 21 of a photoresist film is formed on the top faces of the drift layer 2 and the current spreading layer 3 by a photolithographic technology. The mask pattern 21 has an opening where a source region is to be formed in plan view in the active part 101, for example, in a position overlapping with the base region 5, and covers the voltage withstanding structure part 102 and the region 103. The mask pattern 21 is used as an ion implantation mask, and n type impurities such as phosphorus (P), arsenic (As), antimony (Sb), or nitrogen (N) are selectively ion implanted. As a result, an n⁺ type source region 6 is selectively formed on the top face side of the base region 5. The n type impurities are impurities that are ion implanted in a semiconductor material to convert the semiconductor material into an n type.

The ion implantation in the source region 6 breaks the 4H-SiC structure of the top face side of the source region 6 to form an amorphous structure. The ion implantation temperature is set low for breaking the 4H-SiC structure. By low-temperature ion implantation of impurities at a high concentration, the 4H-SiC structure can be broken. The ion implantation temperature is set, for example, at about not less than 20° C. and less than 300° C. The temperature limit at which the 4H-SiC structure can be broken is about 300° C., and thus the ion implantation temperature may be set, for example, at 200° C. or less. The dose amount at ion implantation is set, for example, at about 2×10¹⁵ cm⁻² or more and 1×10¹⁶ cm⁻² or less. The mask pattern 21 is then removed. The mask pattern 21 may be, for example, a hard mask pattern formed of an oxide film.

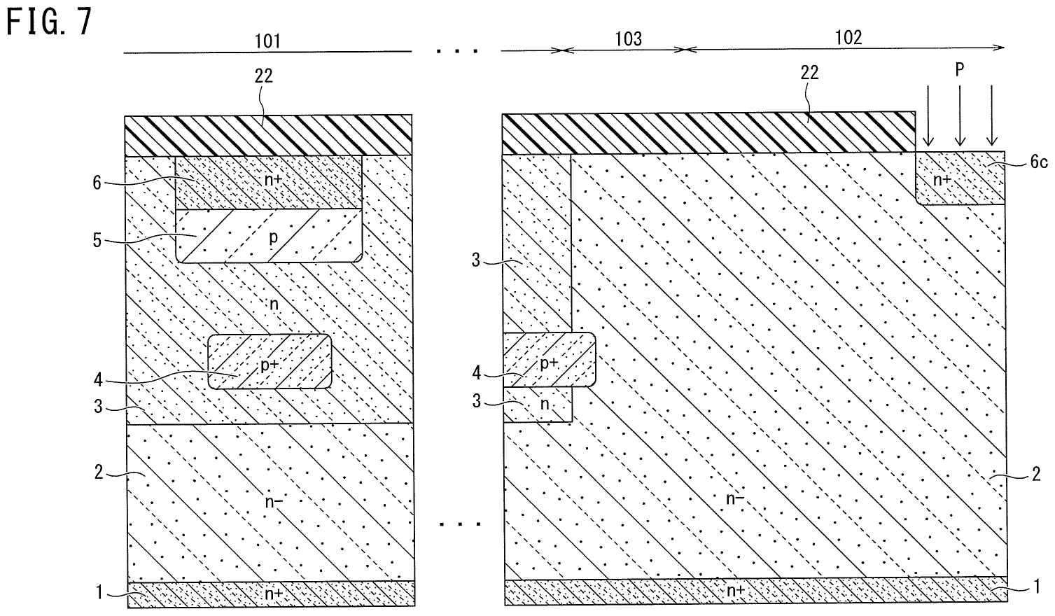

As illustrated in FIG. 7, a mask pattern 22 of a photoresist film is formed on the top faces of the drift layer 2 and the current spreading layer 3 by a photolithographic technology. The mask pattern 22 has an opening where a channel stopper region 6c is to be formed in plan view in the voltage withstanding structure part 102 and covers the active part 101 and the region 103. More specifically, the mask pattern 22 has an opening in a region along the outer periphery portion of the voltage withstanding structure part 102 in plan view. The mask pattern 22 is then used as an ion implantation mask, and n type impurities such as phosphorus (P), arsenic (As), antimony (Sb), or nitrogen (N) are selectively ion implanted. As a result, an n⁺ type channel stopper region 6c is formed on the top face side of the drift layer 2 in the voltage withstanding structure part 102.

The ion implantation in the channel stopper region 6c is performed such that the 4H-SiC structure of the channel stopper region 6c is not excessively broken. More specifically, when the ion implantation temperature is set low, the dose amount at ion implantation is set low. More specifically, when the ion implantation temperature is set, for example, at about not less than 20° C. and less than 300° C., and the dose amount at ion implantation is set at about not less than 1×10¹⁴ cm⁻² and less than 2×10¹⁵ cm⁻², excessive breakage of the 4H-SiC structure can be prevented. When the ion implantation temperature is set high, more specifically, set at a temperature of about 300° C. or more and 600° C. or less, for example, at 500° C., breakage of the 4H-SiC structure can be prevented even when the dose amount at ion implantation is more than the above value. The mask pattern 22 is then removed. The mask pattern 22 may be, for example, a hard mask pattern formed of an oxide film.

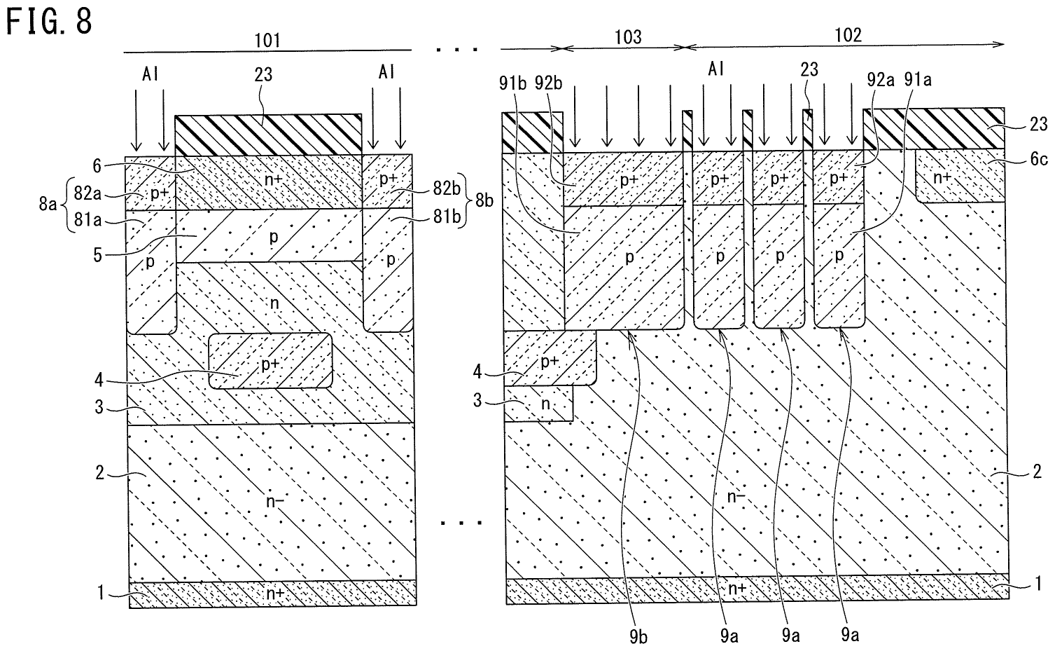

Next, as illustrated in FIG. 8, p type regions are simultaneously formed in the active part 101, the voltage withstanding structure part 102, and the region 103. More specifically, a region 8a including an buried region 81a and a base contact region 82a, a region 8b including an buried region 81b and a base contact region 82b, field relaxation regions 9a, and a ring region 9b are simultaneously formed. First, a mask pattern 23 of a photoresist film is formed on the top faces of the drift layer 2 and the current spreading layer 3 by a photolithographic technology. The mask pattern 23 has openings in positions adjacent to the source region 6 in plan view in the active part 101, openings where field relaxation regions 9a are to be formed in plan view in the voltage withstanding structure part 102, and an opening where a ring region 9b is to be formed in plan view in the region 103. The mask pattern 23 is used as an ion implantation mask to selectively ion implant p type impurities such as aluminum (Al). More specifically, p type impurities are implanted in multiple stages along the depth direction. Accordingly, base contact regions 82a, 82b and second portions 92a, 92b located shallower in the depth direction and buried regions 81a, 81b and first portions 91a, 91b located deeper in the depth direction are formed with the single mask pattern 23. The p type impurities are impurities that are ion implanted in a semiconductor material to convert the semiconductor material into a p type.

The ion implantation in the buried regions 81a, 81b, the base contact regions 82a, 82b, the first portions 91a, 91b, and the second portions 92a, 92b is performed such that the 4H-SiC structure is not excessively broken. More specifically, when the ion implantation temperature is set low, the dose amount at ion implantation is set low. More specifically, when the ion implantation temperature is set, for example, at about not less than 20° C. and less than 300° C., and the dose amount at ion implantation is set at about not less than 1×10¹⁴ cm⁻² and less than 2×10¹⁵ cm⁻², excessive breakage of the 4H-SiC structure can be prevented. When the ion implantation temperature is set high, more specifically, set at a temperature of about 300° C. or more, for example, at 500° C., breakage of the 4H-SiC structure can be prevented even when the dose amount at ion implantation is more than the above value. The mask pattern 23 is then removed. The mask pattern 23 may be, for example, a hard mask pattern formed of an oxide film.

Next, an activation annealing (heat treatment) step is performed. In the activation annealing step, activation annealing, for example, at about 1,600° C. or more and 1,900° C. or less simultaneously activates the p type impurities or the n type impurities that have been ion implanted in the gate bottom protection region 4, the base regions 5a, 5b, the source regions 6a, 6b, the buried regions 81a, 81b, the base contact regions 82a, 82b, the field relaxation regions 9a, the ring region 9b, and the like. By the activation, at least a part of the amorphous structure of the source regions 6a, 6b is recrystallized into 3C-SiC, and accordingly, source regions 6a, 6b containing 3C-SiC are formed. The channel stopper region 6c, the buried regions 81a, 81b, the base contact regions 82a, 82b, the field relaxation regions 9a, and the ring region 9b are still 4H-SiC even after recrystallization.

This embodiment exemplifies a case in which activation annealing is performed once after all the ion implantation steps are completed, but activation annealing may be performed multiple times after each ion implantation step. A cap film of carbon (C) may be formed before activation annealing, activation annealing may be performed with the cap film, and the cap film may be removed after the activation annealing.

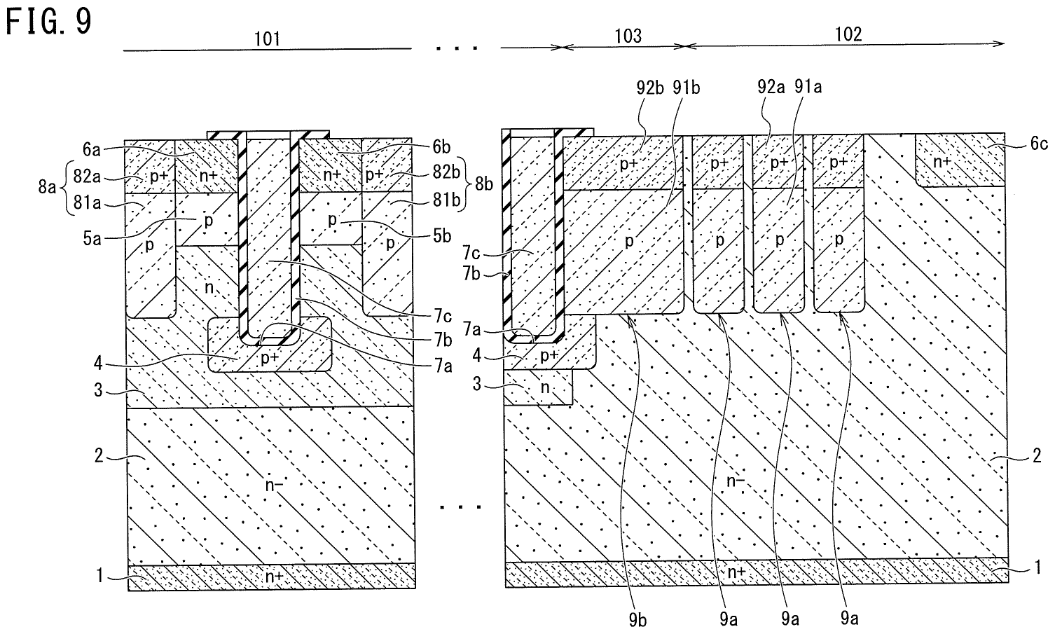

Next, as illustrated in FIG. 9, an insulated gate electrode structures (7b, 7c) forming step is performed. First, a trench forming step is performed. In the trench forming step, a hard mask pattern of an oxide film or the like is formed on the top face of the SiC by a photolithographic technology, a dry etching technology, a CVD technology, or the like. The hard mask pattern has an opening where a trench is to be formed. The hard mask pattern is then used as an etching mask to selectively form a trench 7a from the top face of the source region 6 in the depth direction by a dry etching technology such as reactive ion etching (RIE). In place of the hard mask pattern, a photoresist film may be used as the etching mask. The trench 7a penetrates the source region 6 and the base region 5, further digs the upper part of the current spreading layer 3, and reaches the gate bottom protection region 4. The source region 6 is divided into source regions 6a, 6b, and the base region 5 is divided into base regions 5a, 5b. The etching mask is then removed.

A gate insulating film/gate electrode forming step is then performed. In the gate insulating film/gate electrode forming step, a gate insulating film 7b is formed on the bottom face and side faces of the trench 7a by a CVD technology, a high temperature oxidation (HTO) method, a thermal oxidation method, or the like. Next, a polysilicon layer (doped polysilicon layer) containing impurities such as phosphorus (P) and boron (B) at a high concentration is deposited by a CVD technology or the like such that the inside of the trench 7a is embedded. Then, a part of the polysilicon layer and a part of the gate insulating film 7b are selectively removed by a photolithographic technology and dry etching. As a result, as illustrated in FIG. 9, an insulated gate electrode structure (7b, 7c) including the gate insulating film 7b and the gate electrode 7c is form so as to be in contact with the source regions 6a, 6b and the base regions 5a, 5b.

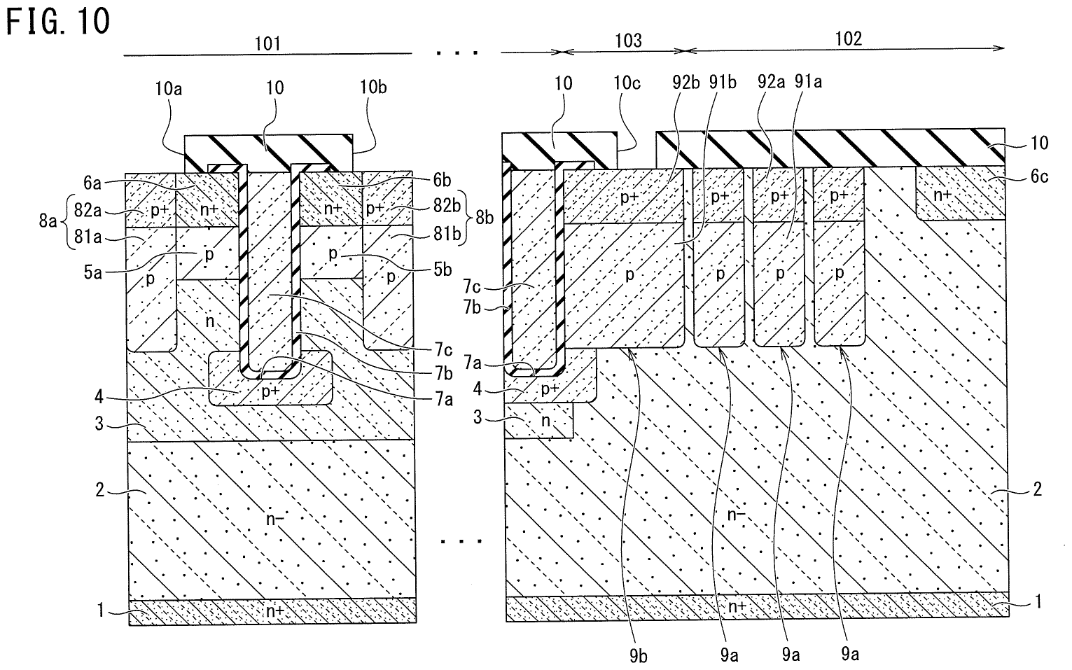

Next, as illustrated in FIG. 10, an insulating film 10 as an inorganic insulating film is deposited on the top face of the SiC by a CVD technology or the like. A part of the insulating film 10 is selectively removed by a photolithographic technology, a dry etching technology, or the like to make, in the insulating film 10, contact holes 10a, 10b through which at least a part of the top faces of the source regions 6a, 6b and the base contact regions 82a, 82b is exposed. In addition, a contact hole 10c through which a part of the top face of the ring region 9b is exposed is made. Of the insulating film 10, a portion covering the voltage withstanding structure part 102 is not removed. Heat treatment (reflow) may then be performed for planarization of the insulating film 10.

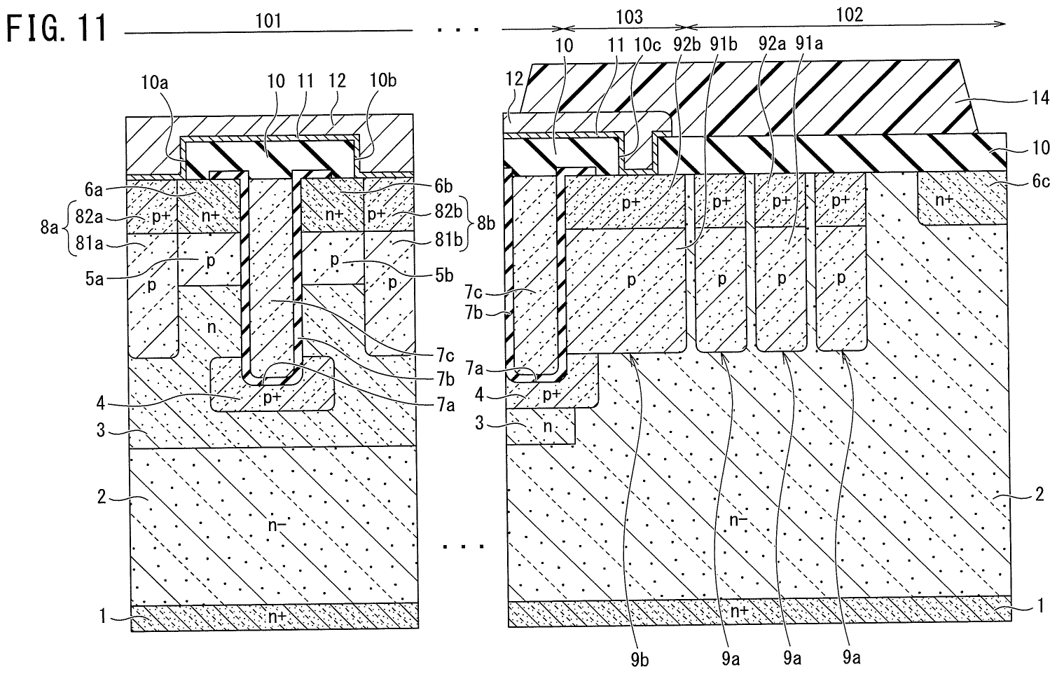

Next, as illustrated in FIG. 11, a barrier metal layer 11 and a source wiring electrode 12 are sequentially formed by a sputtering technology, an evaporation method, or the like so as to cover the top face and side faces of the insulating film 10 and the top faces of the source regions 6a, 6b, the base contact regions 82a, 82b, and the ring region 9b, and a source electrode (11, 12) is formed. The barrier metal layer 11 is in contact with the source regions 6a, 6b, the base contact regions 82a, 82b, and the ring region 9b. The barrier metal layer 11 is in ohmic contact with the source regions 6a, 6b at a low resistance.

Next, as illustrated in FIG. 11, an insulating film 14 as an organic insulating film is formed on the top face of the insulating film 10 such that the outer peripheral edge portion overlaps with the channel stopper region 6c in plan view. The insulating film 14 may be formed by a known method. For example, a film may be formed by a known method, and then an excess portion may be removed by a photolithographic technology and a dry etching technology, for example.

Next, the SiC substrate 1 is subjected to grinding, chemical mechanical polishing (CMP), or the like to decrease the thickness from the bottom face side and to adjust the thickness, and a drain region 1 is formed. Next, a drain electrode 13 is formed from gold (Au) or the like on the entire bottom face of the drain region 1 by a sputtering method, an evaporation method, or the like (see FIG. 2). Through the above process, a SiC semiconductor device illustrated in FIG. 2 is completed.

By the method for manufacturing a SiC semiconductor device pertaining to the first embodiment, ion implantation for forming 3C-SiC and ion implantation for forming 4H-SiC are separately performed in different steps even when forming the same conductivity type semiconductor regions. Hence, even when at least a part of the n type source regions 6a, 6b is formed of 3C-SiC, the channel stopper region 6c in the same n type can be formed of 4H-SiC. More specifically, each of the source regions 6a, 6b and the channel stopper region 6c is formed by ion implantation of first conductivity type (n type) impurities, but are formed in separate steps by ion implantation in different dose amounts. Accordingly, even when at least a part of the source regions 6a, 6b is formed of 3C-SiC, the channel stopper region 6c can be formed of 4H-SiC.

In the first embodiment, the source regions 6a, 6b and the channel stopper region 6c are formed in separate steps, and thus the channel stopper region 6c can be formed at a different depth from the depth of the source regions 6a, 6b. This improves the design flexibility.

In the above manufacturing method, the base contact regions 82a, 82b and the second portions 92a, 92b located shallower in the depth direction and the buried regions 81a, 81b and the first portions 91a, 91b located deeper in the depth direction are formed in the same step, but may be formed in separate steps. In the case, first, a part of the n type layer 3b formed of an n type 4H-SiC may be epitaxially grown, and impurities may be ion implanted to form buried regions 81a, 81b, first portions 91a, 91b, and the like. Then, the rest of the n type layer 3b formed of an n type 4H-SiC may be epitaxially grown, and impurities may be ion implanted to form base contact regions 82a, 82b, second portions 92a, 92b, and the like.

In the present embodiment, the channel stopper region 6c is formed of the first conductivity type (n type) but may be formed of the second conductivity type (p type). In the case, second conductivity type (p type) impurities may be ion implanted in place of first conductivity type (n type) impurities to form a channel stopper region 6c. For example, second conductivity type (p type) impurities may be ion implanted to form a channel stopper region 6c simultaneously with the second portions 92a, 92b.

In the above manufacturing method, ion implantation in the source region 6 is followed by ion implantation for forming the channel stopper region 6c. Alternatively, ion implantation for forming the channel stopper region 6c may be followed by ion implantation in the source region 6.

Forming an insulated gate electrode structure so as to be in contact with a source region and a base region means that steps may be performed in any order as long as a resulting SiC semiconductor device 100 has such a structure. For example, in a planar gate type, providing an insulated gate electrode structure may be followed by forming source regions.

### Second Embodiment

A SiC semiconductor device 100 pertaining to a second embodiment differs from the above SiC semiconductor device 100 pertaining to the first embodiment in that at least each portion of the source regions 6a, 6b and the base contact regions 82a, 82b in contact with the source electrode (11, 12) contains an inert gas element and that the base contact regions 82a, 82b contain 3C-SiC and 4H-SiC. The present embodiment will be described while FIG. 2 is diverted.

In the second embodiment, the source regions 6a, 6b may have a lower impurity concentration than that in the SiC semiconductor device 100 pertaining to the first embodiment. More specifically, the source regions 6a, 6b may have an impurity concentration sufficient to operate the transistor, and the concentration is, for example, about 1×10¹⁹ cm⁻³ or more and 1×10²¹ cm⁻³ or less. The base contact regions 82a, 82b also may have an impurity concentration sufficient to operate the transistor, and the concentration is, for example, about 1×10¹⁹ cm⁻³ or more and 1×10²¹ cm⁻³ or less. At least the top face portions of the base contact regions 82a, 82b contain a 3C structure. More specifically, the top face portions of the base contact regions 82a, 82b contains 10% or more of 3C-SiC. The inert gas element contained in the source regions 6a, 6b and the base contact regions 82a, 82b is, for example, helium (He) or argon (Ar). The buried regions 81a, 81b, the field relaxation regions 9a, the ring region 9b, and the channel stopper region 6c each have an impurity concentration of about 1×10¹⁹ cm⁻³ or more and 1×10²¹ cm⁻³ or less.

### <Method for Manufacturing SiC Semiconductor Device>

An example method for manufacturing the SiC semiconductor device 100 pertaining to the second embodiment will next be described. In the method for manufacturing the SiC semiconductor device pertaining to the second embodiment, the active part 101 is subjected ion implantation of inert gas elements for breaking the 4H-SiC structure. For the method for manufacturing the SiC semiconductor device 100 pertaining to the second embodiment, only the different points from the method for manufacturing the SiC semiconductor device 100 pertaining to the first embodiment will be described. The drawings used for explanation of the manufacturing method of the first embodiment will be appropriately diverted for explanation.

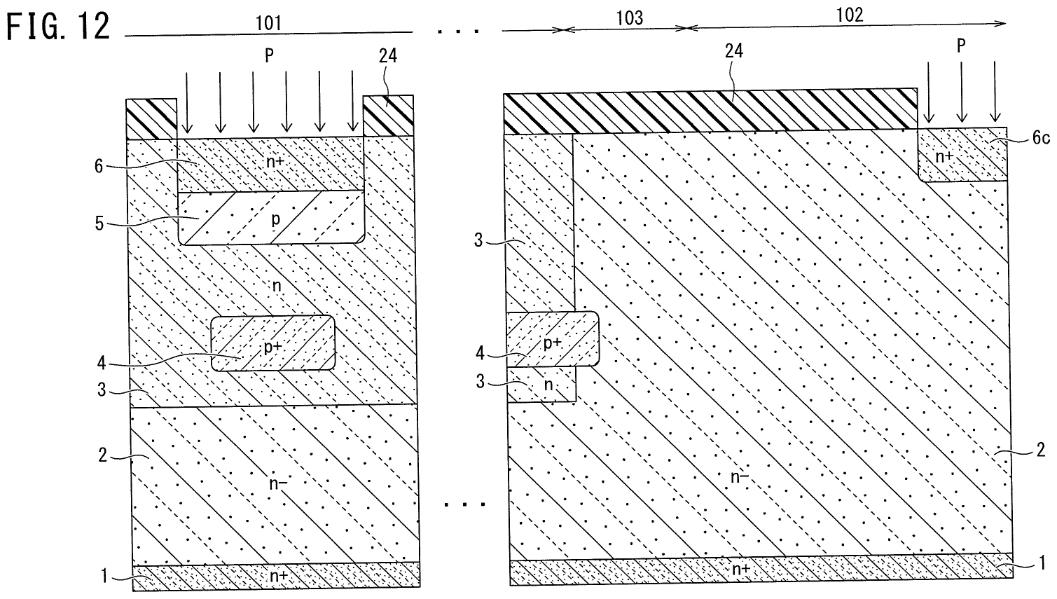

To the steps illustrated in FIG. 5, the method is same as in the first embodiment. Then, in the active part 101 and the voltage withstanding structure part 102, n type regions are simultaneously formed. As illustrated in FIG. 12, a mask pattern 24 of a photoresist film is formed on the top faces of the drift layer 2 and the current spreading layer 3 by a photolithographic technology. The mask pattern 24 has an opening where a source region is to be formed in plan view in the active part 101 and has an opening where a channel stopper region 6c is to be formed in the voltage withstanding structure part 102. The mask pattern 24 is then used as an ion implantation mask, and n type impurities such as phosphorus (P), arsenic (As), antimony (Sb), or nitrogen (N) are selectively ion implanted. As a result, an n⁺ type source region 6 is selectively formed on the top face side of the base region 5, and in the voltage withstanding structure part 102, an n⁺ type channel stopper region 6c is selectively formed on the top face side of the drift layer 2. The ion implantation is performed such that the 4H-SiC structure is not excessively broken. More specifically, when the ion implantation temperature is set, for example, at about not less than 20° C. and less than 300° C., the dose amount at ion implantation may be set at about not less than 1×10¹⁴ cm⁻² and less than 2×10¹⁵ cm⁻². The mask pattern 24 is then removed. The mask pattern 24 may be, for example, a hard mask pattern formed of an oxide film. Then, as illustrated in FIG. 8, p type regions are simultaneously formed in the active part 101, the voltage withstanding structure part 102, and the region 103. The details are as described in the first embodiment.

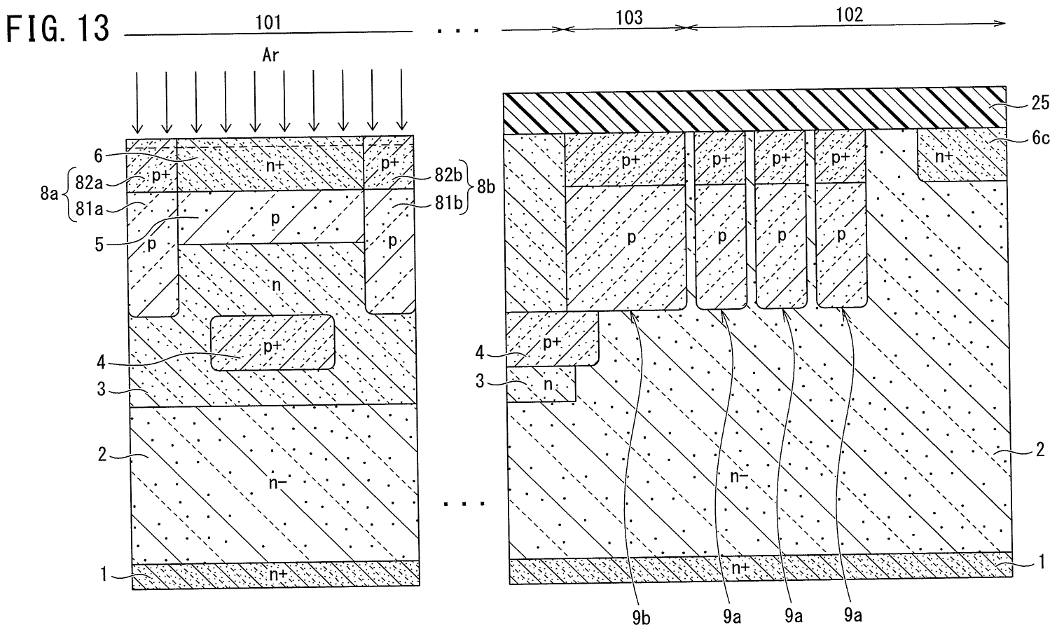

Next, a step of subjecting the source region 6 and the base contact regions 82a, 82b to ion implantation of inert gas elements will be described with reference to FIG. 13. First, a mask pattern 25 of a photoresist film is formed on the top faces of the drift layer 2 and the current spreading layer 3 by a photolithographic technology. The mask pattern 25 may be, for example, a hard mask pattern formed of an oxide film. The mask pattern 25 has an opening where the source region 6 and the base contact regions 82a, 82b are located in the active part 101 and covers the voltage withstanding structure part 102 and the region 103. No opening may be provided where the base contact regions 82a, 82b are located. The mask pattern 25 is then used as an ion implantation mask to selectively ion implant inert gas elements. More specifically, the source region 6 and the base contact regions 82a, 82b are subjected to ion implantation of inert gas elements at a dose amount of about 2×10¹⁵ cm⁻² or more and 1×10¹⁶ cm⁻² or less together with the dose amount of the first conductivity type impurities or with the dose amount of the second conductivity type impurities. The inert gas elements are ion implanted so as to reach the depth indicated by the broken line in the active part 101 in FIG. 13. The ion implantation temperature is set, for example, at about not less than 20° C. and less than 300° C. The inert gas element is, for example, helium (He) or argon (Ar). FIG. 13 illustrates an example in which argon elements are ion implanted. The mask pattern 25 is then removed. Accordingly, the 4H-SiC structure of the active part 101 can be broken, and the subsequent activation annealing can form 3C-SiC regions in the source region 6 and the base contact regions 82a, 82b in the active part 101. The steps after FIG. 13 are the same as in the first embodiment and will not be described.

The dose amount of the inert gas elements may be about 2×10¹⁵ cm⁻² or more and 1×10¹⁶ cm⁻² or less at which the 4H-SiC structure can be broken by only the dose of the inert gas elements.

The source region 6, the base contact regions 82a, 82b, the field relaxation regions 9a, and the ring region 9b are subjected to ion implantation at about not less than 20° C. and less than 300° C. in the above case, but the ion implantation may be performed at a higher temperature of about 300° C. or more, for example, at 500° C. In the case, the dose amount of impurities may be larger than the above value. The dose amount of the inert gas elements may be set at about 2×10¹⁵ cm⁻² or more and 1×10¹⁶ cm⁻² or less.

In the above explanation of the manufacturing method, ion implantation of impurities is followed by ion implantation of inert gas elements. Alternatively, ion implantation of inert gas elements may be followed by ion implantation of impurities.

In the SiC semiconductor device 100 pertaining to the second embodiment, at least the top face portions of the base contact regions 82a, 82b contain a 3C structure, and thus the base contact regions 82a, 82b can be in ohmic contact with the source electrode (11, 12) at a low resistance without forming a silicide layer such as a nickel (Ni) silicide layer. Accordingly, disadvantages such as silicide layer release can be suppressed as compared with when a silicide layer is formed.

By the method for manufacturing a SiC semiconductor device 100 pertaining to the second embodiment, the 4H-SiC in the source region 6 and the base contact regions 82a, 82b can be simultaneously broken by ion implantation of inert gas elements, and thus the implantation amount of impurities can be reduced to the extent that the transistor can be operated. This can reduce the total dose amount and can shorten the time for ion implantation as compared with the first embodiment.

In the present embodiment, the channel stopper region 6c is formed of the first conductivity type (n type) but may be formed of the second conductivity type (p type). In the case, in place of first conductivity type (n type) impurities, second conductivity type (p type) impurities may be ion implanted to form a channel stopper region 6c. For example, second conductivity type (p type) impurities may be ion implanted to form a channel stopper region 6c simultaneously with the second portions 92a, 92b.

### Other Embodiments

The first and second embodiments of the present disclosure have been described as above, but the description and drawings constituting a part of the disclosure should not be understood to limit the disclosure. From the disclosure, various alternative embodiments, examples, and operational technologies will be apparent to a person skilled in the art.

For example, as the semiconductor device pertaining to the first or second embodiment, a MOSFET is exemplified, but the present disclosure is also applicable to an insulated gate bipolar transistor (IGBT) having a structure in which a p⁺ type collector region is provided in place of the n⁺ type drain region 1. In addition to the IGBT alone, the present disclosure is further applicable to a reverse conduction IGBT (RC-IGBT) or a reverse blocking insulated gate bipolar transistor (RB-IGBT).

In the first and second embodiments, the field relaxation region 9a has been described as a guard ring but may have a JTE structure.

The configurations disclosed in the first and second embodiments may be appropriately combined to the extent that no inconsistency arises. Needless to say, the disclosure includes various embodiments and the like not described in the above description. The technical scope of the present disclosure is therefore defined only by the invention specifying matters pertaining to the claims and reasonable from the above description.

What is claimed is:

1. A silicon carbide semiconductor device including, in plan view, an active part and a voltage withstanding structure part surrounding a periphery of the active part, the silicon carbide semiconductor device comprising:
a first conductivity type drift layer formed of silicon carbide and provided over the active part and the voltage withstanding structure part;
a second conductivity type base region formed of silicon carbide and provided on a top face side of the drift layer in the active part;
a first conductivity type main region formed of silicon carbide, provided on a top face side of the base region, and containing a 3C structure in at least a top face portion thereof;
a channel stopper region formed of silicon carbide with a 4H structure and provided on the top face side of the drift layer in the voltage withstanding structure part and along an outer periphery of the voltage withstanding structure part in plan view;
an insulated gate electrode structure provided in contact with the main region and the base region; and
an inorganic insulating film provided on a top face of the channel stopper region.

2. The silicon carbide semiconductor device according to claim 1, wherein the insulated gate electrode structure includes
a gate insulating film provided in a trench penetrating the main region and the base region and
a gate electrode provided on the gate insulating film in the trench.

3. The silicon carbide semiconductor device according to claim 1, wherein the channel stopper region is of a first conductivity type or a second conductivity type.

4. The silicon carbide semiconductor device according to claim 1, further comprising an organic insulating film on a top face of the inorganic insulating film.

5. The silicon carbide semiconductor device according to claim 4, wherein an outer peripheral edge portion of the organic insulating film is located to overlap with the channel stopper region in plan view.

6. The silicon carbide semiconductor device according to claim 1, further comprising a main electrode in contact with a top face portion of the main region.

7. The silicon carbide semiconductor device according to claim 1, wherein the main region has an impurity concentration of 1×10²⁰ cm⁻³ or more and 1×10²¹ cm⁻³ or less.

8. The silicon carbide semiconductor device according to claim 1, wherein the channel stopper region has an impurity concentration of 1×10¹⁹ cm⁻³ or more and 3×10²⁰ cm⁻³ or less.

9. A method for manufacturing a silicon carbide semiconductor device having, in plan view, an active part and a voltage withstanding structure part surrounding a periphery of the active part, the method comprising:
providing a first conductivity type drift layer formed of silicon carbide over the active part and the voltage withstanding structure part;
forming a second conductivity type base region formed of silicon carbide on a top face side of the drift layer in the active part;
subjecting a top face side of the base region to ion implantation to form a first conductivity type main region formed of a silicon carbide and containing a 3C structure in at least a top face portion thereof;
subjecting the top face side of the drift layer in the voltage withstanding structure part to ion implantation to form a channel stopper region of silicon carbide with a 4H structure along an outer periphery of the voltage withstanding structure part in plan view;
forming an insulated gate electrode structure in contact with the main region and the base region; and
providing an inorganic insulating film on a top face of the channel stopper region.

10. The method for manufacturing a silicon carbide semiconductor device according to claim 9, wherein the forming an insulated gate electrode structure includes
forming a trench penetrating the main region and the base region,
forming a gate insulating film in the trench, and
forming a gate electrode on the gate insulating film in the trench.

11. The method for manufacturing a silicon carbide semiconductor device according to claim 9, wherein the forming a channel stopper region includes ion implanting a first conductivity type impurity or a second conductivity type impurity.

12. The method for manufacturing a silicon carbide semiconductor device according to claim 9, further comprising forming an organic insulating film on a top face of the inorganic insulating film.

13. The method for manufacturing a silicon carbide semiconductor device according to claim 12, wherein the organic insulating film is formed such that an outer peripheral edge portion thereof overlaps with the channel stopper region in plan view.

14. The method for manufacturing a silicon carbide semiconductor device according to claim 9, further comprising forming a main electrode to be in contact with a top face portion of the main region.

15. The method for manufacturing a silicon carbide semiconductor device according to claim 9, wherein the forming a main region includes ion implanting a first conductivity type impurity in a dose amount of 2×10¹⁵ cm⁻² or more and 1×10¹⁶ cm⁻² or less.

16. The method for manufacturing a silicon carbide semiconductor device according to claim 9, wherein the forming a main region includes ion implanting a first conductivity type impurity and an inert gas element in a total dose amount of 2×10¹⁵ cm⁻² or more and 1×10¹⁶ cm⁻² or less.

17. The method for manufacturing a silicon carbide semiconductor device according to claim 11, wherein the forming a channel stopper region includes ion implanting the first conductivity type impurity or the second conductivity type impurity in a dose amount of not less than 1×10¹⁴ cm⁻² and less than 2×10¹⁵ cm⁻².

18. The method for manufacturing a silicon carbide semiconductor device according to claim 15, wherein the first conductivity type impurity is phosphorus, arsenic, antimony, or nitrogen.

19. The method for manufacturing a silicon carbide semiconductor device according to claim 17, wherein
the first conductivity type impurity is phosphorus, arsenic, antimony, or nitrogen, and
the second conductivity type impurity is aluminum.
